(19) United States
(12) Patent Application Publication
(10) Pub. No.: US 2007/0028956 A1
(43) Pub. Date: Feb. 8, 2007

(54) Methods of forming thermoelectric devices including superlattice structures of alternating layers with heterogeneous periods and related devices

(76) Inventors: Rama Venkatasubramanian, Cary, NC (US); Edward P. Siivola, Raleigh, NC (US); Brooks C. O'Quinn, Lillington, NC (US); James Christopher Caylor, Durham, NC (US); Jonathan M. Pierce, Raleigh, NC (US)

Correspondence Address: MYERS BIGEL SIBLEY & SAJOVEC, PO BOX 37428, RALEIGH, NC, 27627, US

(21) Appl. No.: 11/402,546

(22) Filed: Apr. 12, 2006

Related U.S. Application Data
(60) Provisional application No. 60/670,583, filed on Apr. 12, 2005.

(51) Int. Cl. H01L 35/34; H01L 35/16

(52) U.S. Cl. 136/201; 136/238

(57) ABSTRACT

Forming a thermoelectric device may include forming a thermoelectric superlattice including a plurality of alternating layers of different thermoelectric materials wherein a period of the alternating layers varies over a thickness of the superlattice. More particularly, forming the superlattice may include depositing the superlattice on a single crystal substrate using epitaxial deposition. In addition, the single crystal substrate may be removed from the superlattice, and a second thermoelectric superlattice may be provided with the first and second thermoelectric superlattices having opposite conductivity types. Moreover, the first and second thermoelectric superlattices may be thermally coupled in parallel between two thermally conductive plates while electrically coupling the first and second thermoelectric superlattices in series. Related materials and devices and structures are also discussed.

### RELATED APPLICATIONS

The present application claims the benefit of priority from U.S. Provisional Application No. 60/670,583 filed Apr. 12, 2005, the disclosure of which is hereby incorporated herein in its entirety by reference.

### STATEMENT REGARDING GOVERNMENT SUPPORT

This invention was made with Government support under U.S. Navy Contract No. N00014-97-C-0211 awarded by the Defense Advanced Research Projects Agency through the Office of Naval Research, and under U.S. Army Contract No. DAAD19-01-C-0010 awarded by the Defense Advanced Research Projects Agency through the Army Research Office. The Government has certain rights in the invention.

### FIELD OF THE INVENTION

The present invention relates to the field of electronics, and more particularly to methods of forming thermoelectric devices for thermoelectric cooling and/or power generation and related devices.

### BACKGROUND

Thermoelectric materials may be used to provide cooling and/or power generation according to the Peltier effect. Thermoelectric materials are discussed, for example, in the reference by Venkatasubramanian et al. entitled “Phonon-Blocking Electron-Transmitting Structures” (18^{th} International Conference On Thermoelectrics, 1999), the disclosure of which is hereby incorporated herein in its entirety by reference.

Application of solid state thermoelectric cooling may be expected to improve the performance of electronics and sensors such as, for example, RF receiver front-ends, infrared (IR) imagers, ultra-sensitive magnetic signature sensors, and/or superconducting electronics. Bulk thermoelectric materials typically based on p—BiₓSb₂₋ₓTe₃ and n—Bi₂Te₃₋ₓSeₓ alloys may have figures-of-merit (ZT) and/or coefficients of performance (COP) which result in relatively poor thermoelectric device performance.

The performance of a thermoelectric device may be a function of the figure(s)-of-merit (ZT) of the thermoelectric material(s) used in the device, with the figure-of-merit being given by:
ZT=(α²T/σK_{T}) (equation 1)
where α, T, σ, K_{T} are the Seebeck coefficient, absolute temperature, electrical conductivity, and total thermal conductivity, respectively. The material-coefficient Z can be expressed in terms of lattice thermal conductivity (K_{L}), electronic thermal conductivity (Kₑ) and carrier mobility (μ), for a given carrier density (ρ) and the corresponding α, yielding equation (2) below:
Z=α²σ/(K_{L}+Kₑ)=α²/[K_{L}/(μρq)+L₀T)] (equation 2)
where, L₀ is the Lorenz number (approximately 1.5×10⁻⁸V²/K² in non-degenerate semiconductors). State-of-the-art thermoelectric devices may use alloys, such as p—BiₓSb₂₋ₓTe_{3-y}Se_{y}(x≈0.5, y≈0.12) and n—Bi₂(Se_{y}Te_{1-y})₃ (y≈0.05) for the 200 degree K to 400 degree K temperature range. For certain alloys, K_{L} may be reduced more strongly than μ leading to enhanced ZT.

A ZT of 0.75 at 300 degree K in p-type BiₓSb₂₋ₓTe₃ (x≈1) was reported forty years ago. See, for example Wright, D. A., Nature vol. 181, pp. 834 (1958). Since then, there has been relatively modest progress in the ZT of thermoelectric materials near 300 degree K (i.e., room temperature). A ZT of about 1.14 at 300 degree K for bulk p-type (Bi₂Te₃)_{0.25} (Sb₂Te₃)_{0.72} (Sb₂Se₃)_{0.03} alloy has been discussed for example, in the reference by Ettenberg et al. entitled “A New N-Type And Improved P-Type Pseudo-Ternary (Bi₂Te₃)(Sb₂Te₃)(Sb₂Se₃) Alloy For Peltier Cooling,” (Proc. of 15^{th} Inter. Conf. on Thermoelectrics, IEEE Catalog. No. 96TH8169, pp. 52-56, 1996), the disclosure of which is hereby incorporated herein in its entirety by reference.

Accordingly, there continues to exist a need in the art for thermoelectric materials providing improved thermoelectric cooling and/or power generation.

### SUMMARY

According to some embodiments of the present invention, a method of forming a thermoelectric device may include forming a thermoelectric superlattice including a plurality of alternating layers of different thermoelectric materials a period of the alternating layers varying over a thickness of the superlattice. More particularly, forming the superlattice may include depositing the superlattice on a single crystal substrate using epitaxial deposition. In addition, the single crystal substrate may be removed from the superlattice, and a second thermoelectric superlattice may be formed with the first and second thermoelectric superlattices having opposite conductivity types. Moreover, the first and second thermoelectric superlattices may be thermally coupled in parallel between two thermally conductive plates and the first and second thermoelectric superlattices may be electrically coupled in series.

The alternating layers of different thermoelectric materials may include alternating layers of Bi₂Te₃ and Sb₂Te₃, and/or the superlattice may include a p-type conductivity superlattice. In an alternative, the alternating layers of different thermoelectric materials may include alternating layers of Bi₂Te₃ and Bi₂Te₃₋ₓSeₓ, or alternating layers of n—PbTe and n—PbTeSe, or alternating layers of n—Bi₂Te₃ and n—InₓTe_{y}, and the superlattice may include an n-type conductivity superlattice.

The alternating layers may include alternating layers of two different materials with a period of the alternating layers being defined as a combined thickness of two adjacent layers of the different materials. A first period of a first region of the superlattice may be at least 10 percent greater than a second period of a second region of the superlattice, and more particularly, at least 20 percent greater than a second period of a second region of the superlattice, and still more particularly, at least 40 percent greater than a second period of a second region of the superlattice.

For example, a first region of the superlattice may have a first thickness in the range of about 1 micrometer to about 7 micrometers, a second region of the superlattice may have a second thickness in the range of about 1 micrometers to about 7 micrometers. Moreover, the first region may have a first period in the range of about 20 Angstroms to about 100 Angstroms, the second region may have a second period in the range of about 0.20 Angstroms to about 100 Angstroms, and the second period may be at least 10 percent greater than the first period. In addition, a third region of the superlattice may have a third thickness in the range of about 1 micrometer to about 7 micrometers, the third region may have a third period in the range of about 20 Angstroms to about 100 Angstroms, and the third period may be at least 10 percent greater than the second period. More particularly, the superlattice may have a total thickness in the range of about 3 micrometers to about 15 micrometers, and more particularly, in the range of about 5 micrometers to about 15 micrometers.

According to some other embodiments of the present invention, a thermoelectric device may include a thermoelectric superlattice having a plurality of alternating layers of different thermoelectric materials, and a period of the alternating layers may vary over a thickness of the superlattice. In addition; a second thermoelectric superlattice may be provided with the first and second thermoelectric superlattices having opposite conductivity types, the first and second thermoelectric superlattices may be thermally coupled in parallel between two thermally conductive plates, and the first and second thermoelectric superlattices may be electrically coupled in series.

For example, the alternating layers of different thermoelectric materials may include alternating layers of Bi₂Te₃ and Sb₂Te₃, and/or the superlattice may be a p-type conductivity superlattice. In an alternative, the alternating layers of different thermoelectric materials may include alternating layers of Bi₂Te₃ and Bi₂Te₃₋ₓSeₓ, or alternating layers of n—PbTe and n—PbTeSe, or alternating layers of n—Bi₂Te₃ and n—InₓTe_{y}, and/or the superlattice may include an n-type conductivity superlattice.

The alternating layers may include alternating layers of two different materials with a period of the alternating layers being defined as a combined thickness of two adjacent layers of the different materials. For example, a first period of a first region of the superlattice may be at least 10 percent greater than a second period of a second region of the superlattice, and more particularly, at least 20 percent greater than a second period of a second region of the superlattice, and still more particularly, at least 40 percent greater than a second period of a second region of the superlattice.

A first region of the superlattice may have a first thickness in the range of about 1 micrometer to about 7 micrometers, a second region of the superlattice may have a second thickness in the range of about 1 micrometers to about 7 micrometers. Moreover, the first region may have a first period in the range of about 20 Angstroms to about 100 Angstroms, the second region may have a second period in the range of about 20 Angstroms to about 100 Angstroms, and the second period may be at least 0 percent greater than the first period. In addition, a third region of the superlattice may have a third thickness in the range of about 1 micrometer to about 7 micrometers, the third region may have a third period in the range of about 20 Angstroms to about 100 Angstroms, and the third period may be at least 10 percent greater than the second period. For example, the superlattice may have a total thickness in the range of about 3 micrometers to about 15 micrometers, and more particularly, in the range of about 5 micrometers to about 15 micrometers.

According to still other embodiments of the present invention a method of forming a thermoelectric device may include providing first and second thermoelectric elements of a same conductivity type, with each of the first and second thermoelectric elements including a respective superlattice of alternating layers of different thermoelectric materials. Moreover, respective surfaces of the first and second thermoelectric elements may be bonded so that a path of current through the first and second thermoelectric elements passes through the alternating layers of the first and second thermoelectric elements.

Bonding the respective surfaces may include solder bonding the respective surfaces of the first and second thermoelectric elements, for example, using a solder such as tin (Sn). More particularly, bonding the respective surfaces may include forming first and second barrier metal layers on the respective surfaces of the first and second thermoelectric elements and forming a solder bond between the first and second barrier metal layers. Moreover, the solder bond and the first and second barrier metal layers may include different metals. Bonding the respective surfaces may also include forming first and second adhesion metal layers on the respective surfaces of the first and second thermoelectric elements before forming the first and second barrier metal layers, and the first and second adhesion metal layers and the first and second barrier metal layers may include different metals.

The first and second thermoelectric elements may be thermally coupled in series between two thermally conductive plates, and the first and second thermoelectric elements may have a first conductivity type. In addition, a third thermoelectric element may be thermally coupled between the two thermally conductive plates with the third thermoelectric element having a second conductivity type different than the first conductivity type, and the first, second, and third thermoelectric elements may be electrically coupled in series. A fourth thermoelectric element having the second conductivity type may also be thermally coupled in series with the third thermoelectric element between the first and second thermally conductive plates, and the first, second, third, and fourth thermoelectric elements may be electrically coupled in series.

The first and second thermoelectric elements may include alternating layers of Bi₂Te₃ and Sb₂Te₃, and/or the first and second thermoelectric elements may be p-type conductivity thermoelectric elements. In an alternative, the first and second thermoelectric elements may include alternating layers of Bi₂Te₃ and Bi₂Te₃₋ₓSeₓ, or alternating layers of n—PbTe and n—PbTeSe, or alternating layers of n—Bi₂Te₃ and n—InₓTe_{y}, and/or the first and second thermoelectric elements may be n-type conductivity thermoelectric elements. Moreover, each of the first and second thermoelectric elements may have a same thickness, and a combined thickness through the first and second thermoelectric elements after bonding the first and second thermoelectric elements may be in the range of about 10 to about 20 micrometers.

According to yet other embodiments of the present invention, a thermoelectric device may include first and second thermoelectric elements of a same conductivity type with each of the first and second thermoelectric elements including a respective superlattice of alternating layers of different thermoelectric materials. Respective surfaces of the first and second thermoelectric elements may be bonded with metal therebetween so that a path of current through the first and second thermoelectric elements passes through the alternating layers of the first and second thermoelectric elements.

The respective surfaces may be bonded using solder, such as a solder including tin (Sn). Moreover, first and second barrier metal layers may be provided on the respective surfaces of the first and second thermoelectric elements, and a solder bond may be provided between the first and second barrier metal layers with the solder bond and the first and second barrier metal layers including different metals. In addition, first and second adhesion metal layers may be provided on the respective surfaces of the first and second thermoelectric elements, and the first and second adhesion metal layers and the first and second barrier metal layers may include different metals.

The first and second thermoelectric elements may be thermally coupled in series between first and second thermally conductive plates, and the first and second thermoelectric elements may have a first conductivity type. In addition, a third thermoelectric element may be thermally coupled between the two thermally conductive plates with the third thermoelectric element having a second conductivity type different than the first conductivity type, and the first, second, and third thermoelectric elements may be electrically coupled in series. A fourth thermoelectric element having the second conductivity type may be thermally coupled in series with the third thermoelectric element between the first and second thermally conductive plates, and the first, second, third, and fourth thermoelectric elements may be electrically coupled in series.

The first and second thermoelectric elements may each include alternating layers of Bi₂Te₃ and Sb₂Te₃, and/or the first and second thermoelectric elements may be p-type conductivity thermoelectric elements. In an alternative, the first and second thermoelectric elements may each include alternating layers of Bi₂Te₃ and Bi₂Te₃₋ₓSeₓ, or alternating layers of n—PbTe and n—PbTeSe, or alternating layers of n—Bi₂Te₃ and n—InₓTe_{y}, and/or the first and second thermoelectric elements may be n-type conductivity thermoelectric elements. Moreover, each of the first and second thermoelectric elements may have a same thickness, and a combined thickness through the first and second thermoelectric elements after bonding the first and second thermoelectric elements may be in the range of about 10 to about 20 micrometers.

According to additional embodiments of the present invention, a method of forming a thermoelectric device may include forming a single crystal thermoelectric superlattice having a plurality of alternating layers of different thermoelectric materials. Moreover, a thickness of the single crystal thermoelectric superlattice may be at least about 3 micrometers, and more particularly, at least about 7 micrometers.

The single crystal thermoelectric superlattice may include a p-type conductivity superlattice, and/or the alternating layers of different thermoelectric materials may include alternating layers of Bi₂Te₃ and Sb₂Te₃. The thickness of the p-type single crystal thermoelectric superlattice may be at least about 10 micrometers, and a resistivity of the single crystal thermoelectric superlattice may be at least about 0.6×10⁻³ ohm-cm, and more particularly, the resistivity of the single crystal thermoelectric superlattice may be about 0.8×10⁻³ ohm-cm.

In an alternative, the single crystal thermoelectric superlattice may include an n-type conductivity superlattice, and/or the alternating layers of different thermoelectric materials may include alternating layers of Bi₂Te₃ and Bi₂Te₃₋ₓSeₓ, or alternating layers of n—PbTe and n—PbTeSe, or alternating layers of n—Bi₂Te₃ and n—InₓTe_{y}. The thickness of the single crystal thermoelectric superlattice may be at least about 8 micrometers, and a resistivity of the single crystal thermoelectric superlattice may be at least about 2×10⁻³ ohm-cm, and more particularly, the resistivity of the single crystal thermoelectric superlattice may be about 2.5×10⁻³ ohm-cm.

In addition, a second single crystal thermoelectric superlattice may be formed with the first and second single crystal thermoelectric superlattices having different conductivity types. The first and second single crystal thermoelectric superlattices may be thermally coupled in parallel between first and second thermally conductive plates, and the first and second single crystal thermoelectric superlattices may be electrically coupled in series. Moreover, forming the single crystal thermoelectric superlattice may include forming the single crystal thermoelectric superlattice on a single crystal substrate, and removing the single crystal substrate to allow a device structure to be fabricated.

According to further embodiments of the present invention, a thermoelectric device may include a single crystal thermoelectric superlattice having a plurality of alternating layers of different thermoelectric materials. Moreover, a thickness of the single crystal thermoelectric superlattice may be at least about 3 micrometers, and more particularly, at least about 7 micrometers.

The single crystal thermoelectric superlattice may include a p-type conductivity superlattice, and/or the alternating layers of different thermoelectric materials may include alternating layers of Bi₂Te₃ and Sb₂Te₃. The thickness of the p-type single crystal thermoelectric superlattice may be at least about 10 micrometers, and a resistivity of the single crystal thermoelectric superlattice may be at least about 0.6×10⁻³ ohm-cm, and more particularly, the resistivity of the single crystal thermoelectric superlattice may be about 0.8×10⁻³ ohm-cm.

In an alternative, the single crystal thermoelectric superlattice may include an n-type conductivity superlattice, and/or the alternating layers of different thermoelectric materials may include alternating layers of Bi₂Te₃ and Bi₂Te₃₋ₓSeₓ, or alternating layers of n—PbTe and n—PbTeSe, or alternating layers of n—Bi₂Te₃ and n—InₓTe_{y}. The thickness of the single crystal thermoelectric superlattice may be at least about 3 micrometers, and more particularly, at least about 8 micrometers, and a resistivity of the n-type single crystal thermoelectric superlattice may be at least about 2×10⁻³ ohm-cm, and more particularly, the resistivity of the single crystal thermoelectric superlattice may be about 2.5×10⁻³ ohm-cm.

In addition, a second single crystal thermoelectric superlattice may be provided such that the first and second single crystal thermoelectric superlattices have different conductivity types. Moreover, the first and second single crystal thermoelectric superlattices may be thermally coupled in parallel between the first and second thermally conductive plates, and the first and second single crystal thermoelectric superlattices may be electrically coupled in series.

### BRIEF DESCRIPTION OF THE DRAWINGS

FIG. 1 is a graph illustrating intrinsic figures-of-merit (ZT) as a function of temperature for p-type and n-type superlattice materials.

FIG. 2A is a plan view illustrating a small footprint thermoelectric module as may be appropriate for laser cooling and/or microprocessor hot-spot thermal management, shown as an insert on a penny.

FIG. 2B is a plan view illustrating a large footprint thermoelectric module appropriate for large-area applications such as infrared (IR) focal-plane arrays shown beside a penny.

FIG. 3 is a graph illustrating cooling curves for a 600 μm (micrometer)×600 μm (micrometer) thermoelectric spot cooler that may provide a cooling power density in the range of about 150 W/cm² at a module level.

FIG. 4 is a graph illustrating a comparison of cooling densities of temperature differences that may be obtained with p-n couples using superlattice thermoelectric materials and with p-n couples using bulk thermoelectric materials.

FIG. 5 illustrates intrinsic figures-of-merit (ZT_{intrinsic}) and related parameters that may be available for p-type and n-type Bi₂Te₃-based superlattice thermoelectric elements.

FIG. 6 illustrates extrinsic figures-of-merit (ZT_{extrinsic}) and related parameters that may be available at p-type element and n-type thermoelectric element levels with each element including two ohmic contacts.

FIG. 7 is a graph illustrating extrinsic figures-of-merit (T_{extrinsic}) as functions of contact resistivity for a 5 μm (micrometer) thick n-type superlattice thermoelectric element and for a 10 μm (micrometer) thick superlattice thermoelectric element.

FIG. 8 illustrates a combined extrinsic figure-of-merit for an inverted p-n thermoelectric couple (ZT_{IC}) and related parameters that may be available for a series coupling of a p-type element and an n-type element.

FIG. 9 illustrates the addition of metal posts to the ohmic contacts of the p-type and n-type thermoelectric elements of the inverted p-n couple for attachment to a split-metal header, and a resulting extrinsic figure-of-merit after attachment.

FIG. 10 is a graph illustrating extrinsic figures-of-merit for thermoelectric device modules as functions of specific plate-attach resistivity.

FIG. 11 is a graph illustrating extrinsic figures-of-merit for thermoelectric device modules as functions of specific plate-attach resistivities for modules including thermoelectric elements with different superlattice epitaxial layer thicknesses and for 2p-2n and 1p-1n configurations using intrinsic materials discussed with respect to FIG. 5.

FIG. 12 is a cross-sectional view illustrating a superlattice thermoelectric element having regions of different superlattice periods across a thickness thereof according to embodiments of the present invention.

FIGS. 13a-d are cross-sectional views illustrating operations of forming thermoelectric elements having regions of different superlattice periods and related devices according to embodiments of the present invention.

FIG. 14 is a cross-sectional view illustrating a thermoelectric element including two bonded sub-elements according to embodiments of the present invention.

FIGS. 15a-d are cross-sectional views illustrating operations of forming thermoelectric elements including bonded sub-elements and related devices according to embodiments of the present invention.

FIGS. 16a-c are cross-sectional views illustrating operations if forming thick superlattice thermoelectric elements according to embodiments of the present invention.

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Examples of embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety.

As integrated circuit chip manufacturers reduce line widths and/or feature sizes (for example, to 90 nm and even 65 nm) and/or as integrated circuit chips are used to run more computationally-complex applications, power densities may increase further. Higher temperature and/or more integrated circuit chip hot spots may thus impact reliability and/or performance. Cooling of these hot spots, for example, may thus be provided for integrated circuit chips used in wireless, cellular, and/or mobile communications devices running advanced (e.g., high speed) algorithms for digital voice, video, and/or data operations, particularly where error detection and/or error correction algorithms are used. Currently, integrated circuit hot spots may generate heat in the range of 100 W/cm² to 200 W/cm² on the backside of the silicon chip resulting from heat-fluxes of over 1800 W/cm² on the active side of the silicon chip. In the near future, hot spots on a backside of an integrated circuit chip may be expected to approach 1000 W/cm². Moreover, lower junction temperatures (for transistors on the active side of the integrated circuit chip) may be desired to reduce power consumption and/or to provide more stable operation, for example, by reducing leakage currents for transistors in the off-state.

Accordingly, coolers for integrated circuit devices may be used to provide cooling-on-demand and/or to increase system efficiency while managing a higher density of heat fluxes at an integrated circuit chip hot spot(s). More particularly, relatively low-profile solid-state thermoelectric coolers using superlattice thermoelectric materials may provide hot spot cooling for integrated circuit chips and/or scalable refrigeration for an entire integrated circuit chip, for example, to reduce leakage currents. Thermoelectric superlattice materials are discussed, for example, in the reference by Venkatasubramanian et al. entitled “Phonon-Blocking Electron-Transmitting Structures” (18^{th} International Conference On Thermoelectrics, 1999), the disclosure of which is hereby incorporated herein in its entirety by reference. Thermoelectric superlattice materials are also discussed, for example, in U.S. Pat. Nos. 6,722,140; 6,662,570; 6,505,468; 6,300,150; and 6,071,351; the disclosures of which are hereby incorporated herein in their entirety by reference. In addition, thermoelectric superlattice materials are discussed, for example, in U.S. Patent Publication Nos.: 2003/0230332; 2003/0131609; 2003/0126865; 2003/0100137; 2003/0099279; 2002/0174660; and 2001/0052234; the disclosures of which are hereby incorporated herein in their entirety by reference.

Superlattice Bi₂Te₃-based thermoelectric materials providing increased figures-of-merit are discussed, for example, in the reference by Venkatasubramanian et al. entitled “Thin-Film Thermoelectric Devices With High Room-Temperature Figures Of Merit” (Nature, Vol. 413, 11 Oct. 2001, pages 597-602) the disclosure of which is hereby incorporated herein in its entirety by reference. Further developments in thermoelectric materials may provide average figures-or-merit (ZT_{avg}) of about 2.4 at 300 degree K (i.e., room temperature) for use in cooling and/or power generation modules. Increased figures-or-merit and site-specific thermal management capability may enable power-efficient system level cooling, cooling for commercial high-performance electronics, and/or power generation for military application. Superlattice thermoelectric couples may provide a temperature differential of about 85 degree K. At volume production, cooling may be provided at a cost of about $0.2/Watt. Superlattice thermoelectric materials may thus be used to provide thermoelectric coolers for microprocessor chip cooling for hot-spot thermal management, for leakage current control, and/or for threshold voltage control.

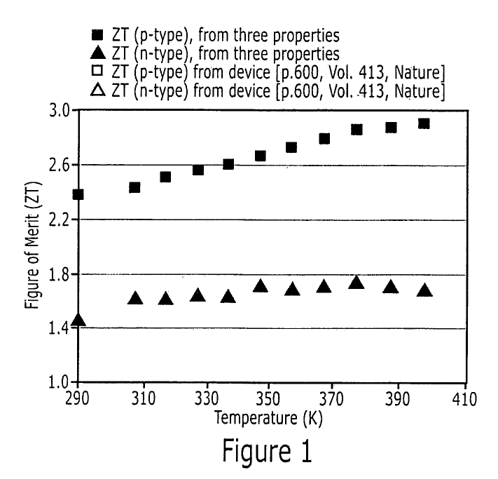

FIG. 1 illustrates intrinsic figures-of-merit (ZT) (as a function of temperature) for p-type and n-type Bi₂Te₃-based thermoelectric superlattice materials. The data of FIG. 1 represents figures-of-merit that may be available for power conversion using fabricated p-n couples taking into consideration parasitics (for example, resulting from thermoelectric-to-metal interconnections) that may reduce full realization of the performance of the thermoelectric superlattice materials. Power conversion data on p-n couples indicates that an effective (or extrinsic) ZT of about 1.3 may be provided.

As discussed in the reference by Venkatasubramanian et al. entitled “Thin-Film Thermoelectric Devices With High Room-Temperature Figures Of Merit”, Bi₂Te₃-based thermoelectric superlattice materials may provide both phonon-blocking and electron-transmission to increase intrinsic figures-of-merit for thermoelectric materials. These Bi₂Te₃-based thermoelectric superlattice materials and/or other thermoelectric materials may be incorporated into p-n couples and into pluralities of p-n couples and/or modules to provide thermoelectric cooling devices with relatively high effective figures-of-merit for laser cooling and/or microprocessor hot-spot cooling.

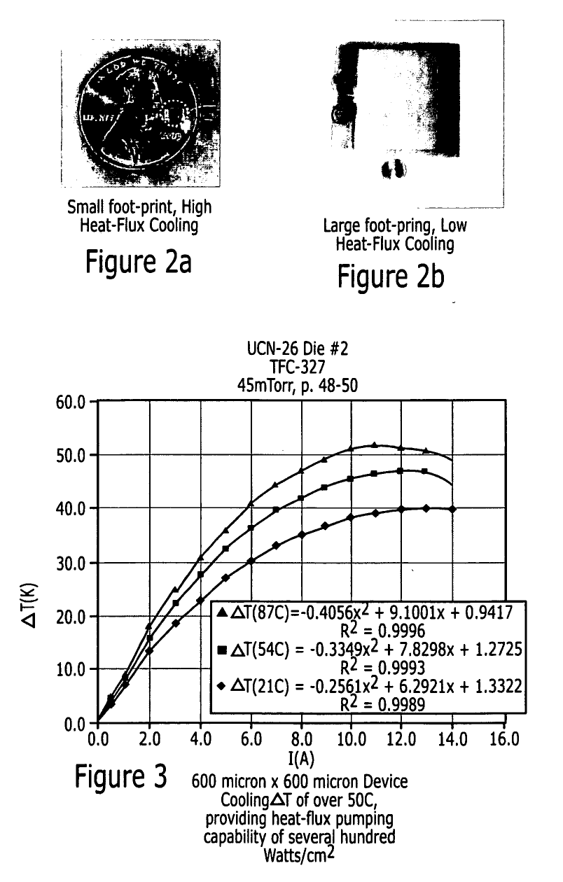

Semiconductor process technologies used to form thermoelectric superlattice thin films may allow flexible module design for a wide range of applications and/or for reductions in design cycle times and/or cost. Sizes of cooling modules may range from relatively small footprint high heat-flux cooling thermoelectric modules for laser cooling and/or microprocessor hot-spot thermal management as shown in FIG. 2a, to relatively large footprint low heat-flux modules for large-area applications such as infrared (IR) focal-plane arrays as shown in FIG. 2b. FIG. 3 is a graph illustrating cooling curves for a 600 μm (micrometer)×600 μm (micrometer) thermoelectric spot cooler that may provide a cooling power density in the range of about 150 W/cm² at a module level. To obtain cooling power densities illustrated in FIG. 3 and/or to provide higher cooling power densities, further increases in intrinsic figures-of-merit, improved interconnections between thermoelectric elements of p-n couples, improved interconnections between p-n couples, and/or interconnections to system interfaces may be used.

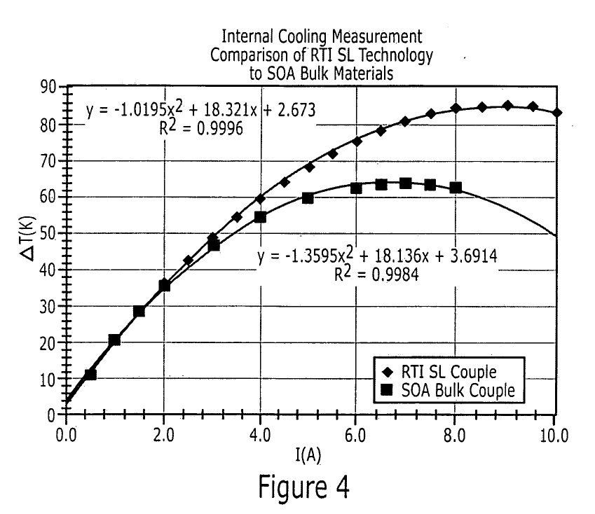

FIG. 4 is a graph illustrating a comparison of temperature differences (ΔT) that may be obtained with p-n couples using superlattice thermoelectric materials and with p-n couples using bulk thermoelectric materials. As shown in FIG. 4, a temperature difference (ΔT) of about 85 degree K may be provided using a superlattice thermoelectric (TE) module, while a bulk thermoelectric module may provide a temperature difference (ΔT) of about 67 degree K. Superlattice thermoelectric materials may thus provide more efficient hot side heat rejection as compared with bulk thermoelectric materials. Accordingly, an increased temperature difference (ΔT) with a higher hot side temperature may allow hot-side heat exchanger components having reduced complexity and/or increased versatility.

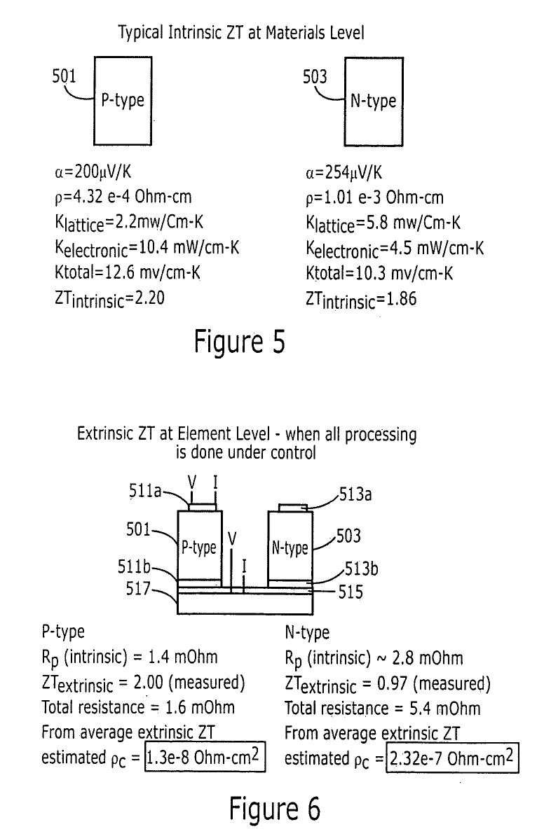

FIGS. 5, 6, 8, and 9 are cross-sectional views illustrating structures that may result at various operations of forming a thermoelectric device according to embodiments of the present invention. In addition, FIGS. 5, 6, 8, and 9 provide various thermoelectric properties of the illustrated structures.

As shown in FIG. 5, a p-type superlattice thermoelectric element 501 and an n-type superlattice thermoelectric element 503 may have the intrinsic thermoelectric properties shown. The p-type and n-type thermoelectric elements 501 and 503 may be formed using epitaxial deposition on different single crystal substrates (such as GaAs substrates) as discussed, for example, in the reference by Venkatasubramanian entitled “Thin-Film Thermoelectric Devices With High Room-Temperature Figures Of Merit” and in U.S. Patent Publication No. 2003/0099279. The substrates may be diced to provide individual thermoelectric elements, and the remaining portions of substrate on the individual thermoelectric elements may be removed, for example, by etching. In FIG. 5, intrinsic thermoelectric parameters are provided with respect to the separate p-type and n-type thermoelectric elements 501 and 503.

As shown in FIGS. 6 and 8, interconnection metallization layers 511a-b and 513a-b may be provided on ends of the thermoelectric elements 501 and 503, and the thermoelectric elements 501 and 503 may be bonded to a metal trace 515 (such as a copper trace) on a thermally conductive plate 517 (also referred to as a header). Each of the interconnection metallization layers may include an adhesion layer (such as a layer of titanium, chromium, and/or tungsten) on the thermoelectric element, and a barrier layer (such as a layer of nickel or gold) on the adhesion layer opposite the thermoelectric element. Moreover, the interconnection metallization layers 511b and 513b may be bonded to the metal trace 515 using a solder, such as a lead-tin solder or a lead free solder.

In FIG. 6, the thermoelectric parameters are provided with respect to the separate p-type and n-type thermoelectric elements 501 and 503 with respective interconnection metallizations and the coupling to the metal trace 515. In FIG. 8, the thermoelectric parameters are provided with respect to the combination of the p-type and n-type thermoelectric elements 501 and 503 with the interconnection metallizations and the coupling through the conductive trace 515.

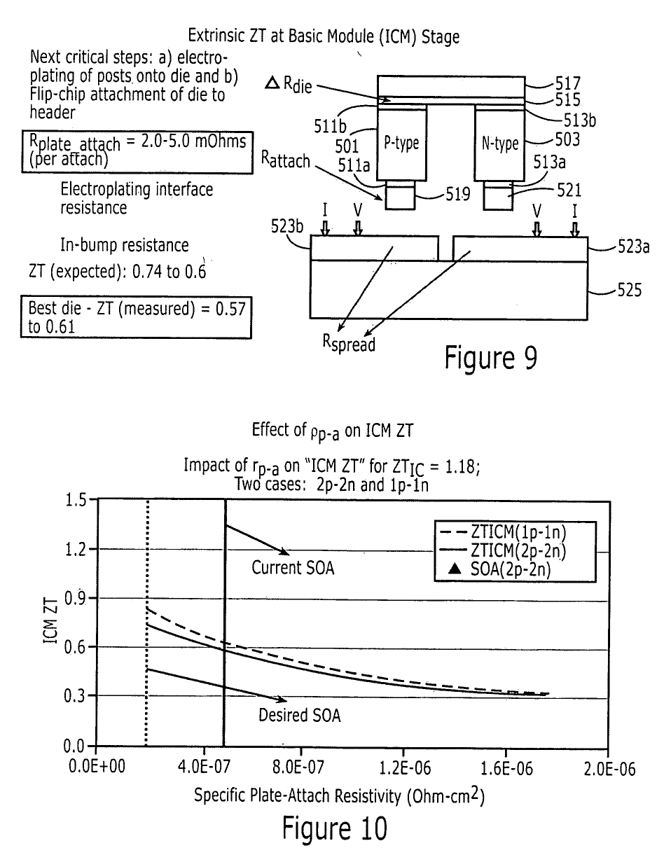

As shown in FIG. 9 metal posts may 519 and 521 may be plated on the interconnection metallization layers 511a and 513a. The metal posts may be used to provide electrical and mechanical coupling to the conductive-traces 523a-b on the thermally conductive plate 525 (also referred to as a header). In FIG. 9, the thermoelectric parameters are provided with respect to the combination of the p-type and n-type thermoelectric elements 501 and 503 with the interconnection metallizations and the couplings through the conductive traces 515 and 523a-b. As shown in FIGS. 5, 6, 8, and 9, an effective figure-of-merit for a thermoelectric device including interconnected thermoelectric elements may be significantly less than an intrinsic figure-of-merit for separate superlattice thermoelectric elements used to make the device.

When combining p-type and n-type thermoelectric elements into couples and/or modules, a “loss” of “intrinsic ZT” may occur as a result of processing, interconnections, etc., together referred to as “parasitics”. FIG. 5 illustrates intrinsic figures-of-merit (ZT) and related parameters that may be available for p-type and n-type Bi₂Te₃-based superlattice thermoelectric elements. As shown in FIG. 5, a p-type Bi₂Te₃-based superlattice thermoelectric element may have an intrinsic figure-of-merit (ZT_{intrinsic}) of about 2.20, and an n-type Bi₂Te₃-based superlattice thermoelectric element may have an intrinsic figure-of-merit (ZT_{intrinsic}) of about 1.86.

FIG. 6 illustrates extrinsic figures-of-merit (ZT_{extrinsic}) and related parameters that may be available at p-type element and n-type element levels with each element including two ohmic contacts and resulting parasitics. As shown in FIG. 6, a p-type Bi₂Te₃-based superlattice thermoelectric element may have an extrinsic figure-of-merit (ZT_{extrinsic}) of about 2.00, and an n-type Bi₂Te₃-based superlattice thermoelectric element may have an extrinsic figure-of-merit (ZT_{extrinsic}) of about 0.97.

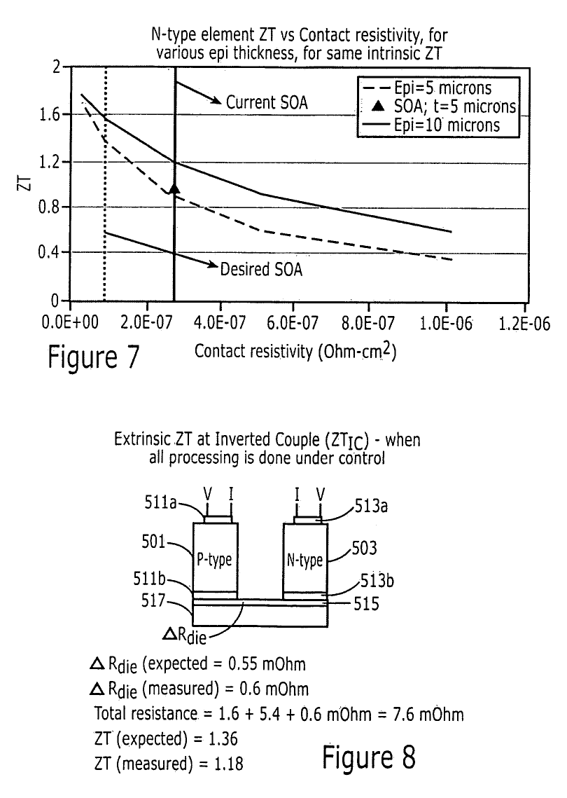

FIG. 7 is a graph illustrating extrinsic figures-of-merit (ZT_{extrinsic}) as a functions of contact resistivity for a 5 micron thick n-type superlattice thermoelectric element and for a 10 micron thick superlattice thermoelectric element, with both thermoelectric elements having the same intrinsic figure-of-merit (ZT_{intrinsic}). As shown, the extrinsic figures-of-merit (ZT_{extrinsic}) may increase with reduced contact resistivity, and the extrinsic figures-of-merit (ZT_{extrinsic}) may increase with increased thickness of the epitaxial superlattice thermoelectric element. Accordingly, reduced contact resistivities may provide increased extrinsic figures-of-merit.

FIG. 8 illustrates a combined extrinsic figure-of-merit for an inverted p-n thermoelectric couple (ZT_{IC}) and related parameters that may be available for a series coupling of a p-type element and an n-type element with the two thermoelectric elements electrically coupled through a metal trace on a substrate and through ohmic contacts provided at both ends of the thermoelectric elements. As shown in FIG. 8, a couple including p-type and n-type Bi₂Te₃-based superlattice thermoelectric elements may have a measured extrinsic inverted couple figure-of-merit (ZT_{IC}) of about 1.2. Accordingly, the inverted couple figure-of-merit may be reduced relative to the intrinsic figures-of-merit of the p-type and n-type thermoelectric elements due to the combination of the ohmic contacts and the metal trace.

FIG. 9 illustrates the addition of metal posts to the ohmic contacts of the p-type and n-type thermoelectric elements of the inverted p-n couple for attachment to a split-metal header, and the resulting extrinsic figure-of-merit after attachment. The resistances resulting from the ohmic contacts, the metal posts, the metal trace on the die, and/or the metal traces on the split metal header may effect the overall extrinsic figure-of-merit for the resulting module. As shown in FIG. 9, the resulting figure-of-merit for the module may be reduced to about 0.6 from the figure-of-merit of about 1.2 for the inverted p-n couple of FIG. 8.

FIG. 10 is a graph illustrating extrinsic figures-of-merit for thermoelectric device modules as functions of specific plate-attach resistivity. More particularly, the extrinsic figures-of-merit are provided for 2p/2n and 1p/1n module configurations. As shown in FIG. 10, an effective figure-of-merit for a thermoelectric device module may be reduced with increased plate-attach resistivities. In a 1p/1n module configuration, one p-type thermoelectric element is electrically coupled between the conducive traces 515 and 523b, and one n-type thermoelectric element is electrically coupled between the conductive traces 515 and 523a. In a 2p/2n module configuration, two p-type thermoelectric elements are electrically coupled in parallel between the conducive traces 515 and 523b, and two n-type thermoelectric elements are electrically coupled in parallel between the conductive traces 515 and 523a.

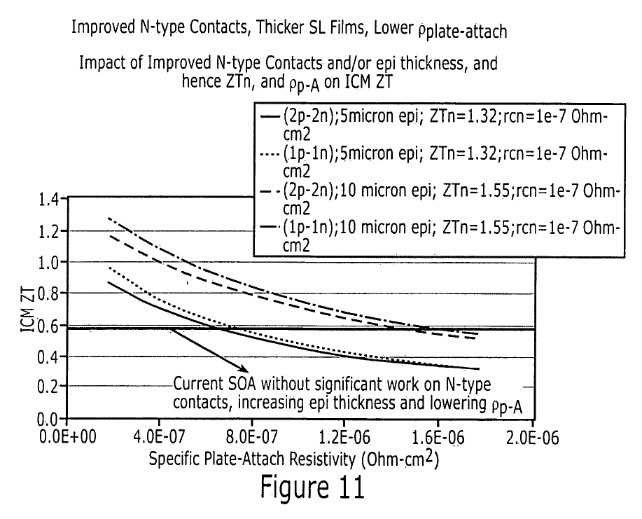

FIG. 11 is a graph illustrating extrinsic figures-of-merit for thermoelectric device modules as functions of specific plate-attach resistivities for modules including thermoelectric elements with different supperlattice epitaxial layer thicknesses and for 2p-2n and 1p-1n configurations. More particularly, the thermoelectric materials of FIG. 5 are used for the thermoelectric elements in the modules of FIG. 11, intrinsic figures-of-merit for the 5 micrometer thick n-type thermoelectric elements are about 1.32, intrinsic figures-of-merit for the 10 micrometer thick n-type thermoelectric elements are about 1.55, and ohmic contacts for the n-type thermoelectric elements are about 1×10⁻⁷ ohm-cm². Accordingly, reductions in plate-attach resistivities may improve figures-of-merit for die-level modules with thermoelectric elements with 5 micrometer epitaxial superlattice layer thicknesses from about 0.6 to 1.

As discussed in greater detail below, thermoelectric device modules with relatively thin epitaxial thermoelectric superlattice layer thicknesses may provide improved high heat-flux pumping conditions. A thinner epitaxial thermoelectric superlattice layer thickness may allow a reduction in defects that may result from strained layer superlattices that may result when using lattice-mismatch between different superlattice layers to provide an acoustic mismatch and a dielectric phonon localization-like effects for reduction in thermal conduction. A thickness of about 5 micrometers for the epitaxial thermoelectric superlattice layer may provide a relatively high extrinsic figure-of-merit at the thermoelectric element level together with relatively low fabrication cost. While 5 and 10 micrometer thicknesses are discussed by way of example, thinner epitaxial thermoelectric superlattice layers/elements may be used for higher heat-flux cooling conditions.

According to embodiments of the present invention, 5 micrometer thick epitaxial thermoelectric superlattice layers/elements may be used to fabricate thermoelectric device modules having thicknesses in the range of about 20 micrometers to about 110 micrometers. Thermoelectric device modules having thicknesses in the range of about 20 to 110 micrometers may facilitate packaging with integrated circuit devices.

As discussed above, thermoelectric elements including superlattices of alternating layers of different thermoelectric materials may be used in thermoelectric devices to provide thermoelectric cooling and/or power generation while reducing undesirable thermal conduction through the superlattice. According to some embodiments of the present invention, a thermoelectric element may include a superlattice wherein a period of the alternating layers of the superlattice varies over a thickness of the superlattice. As discussed herein, the period of a superlattice including alternating layers may be defined as the combined thickness of two adjacent layers of the different materials. While superlattices of repetitive two layer patterns are discussed herein by way of example, superlattices of different patterns may be used according to embodiments of the present invention with a period of the superlattice being defined as a thickness of one cycle of the pattern. In a superlattice including a repetitive pattern of three layers of three different materials, for example, the period may be defined as the combined thickness of three adjacent layers of the three different materials defining one cycle of the pattern. By providing different periods of the superlattice within a same thermoelectric element, performance of the thermoelectric element may be further improved.

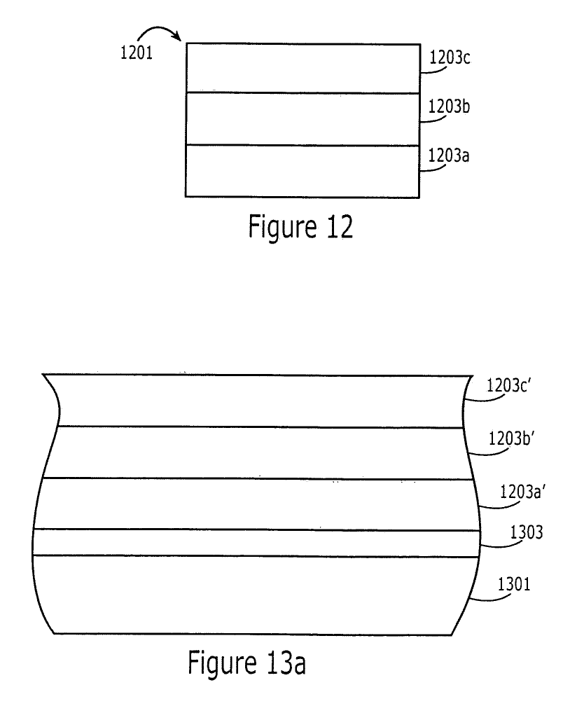

As shown in FIG. 12, a thermoelectric element 1201 may include three different regions 1203a-c across a thickness thereof, and a period of the alternating layers of the superlattice may be different in each of the regions. According to some embodiments of the present invention, the thermoelectric element 1201 may have a p-type conductivity, and the superlattice may include alternating layers of Bi₂Te₃ and Sb₂Te₃. By way of example: the first region 1203a may have alternating layers of 10 Angstrom thick Bi₂Te₃ and 30 Angstrom thick Sb₂Te₃ with a period of about 40 Angstroms and a resistivity of about 1.1×10⁻³ ohm-cm; the second region 1203b may have alternating layers of 10 Angstrom thick Bi₂Te₃ and 40 Angstrom thick Sb₂Te₃ with a period of about 50 Angstroms and a resistivity of about 0.8×10⁻³ ohm-cm; and the third region 1203c may have alternating layers of 10 Angstrom thick Bi₂Te₃ and 50 Angstrom thick Sb₂Te₃ with a period of about 60 Angstroms and a resistivity of about 0.5×10⁻³ ohm-cm. In such a structure, the resulting net resistivity may be about 0.8×10⁻³ ohm-cm.

According to other embodiments of the present invention, the thermoelectric element 1201 may have an n-type conductivity, and the superlattice may include alternating layers of Bi₂Te₃ and BiₓTe₃₋ₓSeₓ, and/or alternating layers of n—PbTe (n-type conductivity PbTe) and n—PbTeSe (n-type conductivity PbTeSe), and/or alternating layers of n—Bi₂Te₃ (n-type conductivity Bi₂Te₃) and n—InₓTe_{y} (n-type conductivity InₓTe_{y}). By way of example, the superlattice may include alternating layers of Bi₂Te₃ and Bi₂Te₃₋ₓSeₓ, (with x in the range of about 0.2 to about 0.4). By way of example: the first region 1203a may have alternating layers of 10 Angstrom thick Bi₂Te₃ and 30 Angstrom thick Bi₂Te₃₋ₓSeₓ with a period of about 40 Angstroms; the second region 1203b may have alternating layers of 10 Angstrom thick Bi₂Te₃ and 40 Angstrom thick Bi₂Te₃₋ₓSeₓ with a period of about 50 Angstroms; and the third region 1203c may have alternating layers of 10 Angstrom thick Bi₂Te₃ and 50 Angstrom thick Bi₂Te₃₋ₓSeₓ with a period of about 60 Angstroms. While thermoelectric elements with three regions having different superlattice periods are discussed by way of example, any number of regions having different superlattice periods greater than two may be provided according to embodiments of the present invention.

According to some embodiments of the present invention, a period of one of the regions 1203a-c may be at least 10 percent greater than a period of another of the regions, and more particularly, at least 20 percent greater, and even at least 40 percent greater. According to embodiments of the present invention with the regions 1203a-c having respective periods of 40 Angstroms, 50 Angstroms, and 60 Angstroms: the period of region 1203b may be about 25 percent greater than the period of region 1203a; the period of region 1203c may be 20 percent greater than the period of region 1203b; and the period of region 1203c may be 50 percent greater than the period of region 1203a.

With either a p-type and/or an n-type thermoelectric element, each of the first second, and third regions 1203a-c may have a thickness in the range of about 1 micrometers to about 7 micrometers; periods of the superlattices in each of the regions 1203a-c may be in the range of about 20 Angstroms to about 100 Angstroms; and a period of one of the regions may be at least 10 percent greater than a period of another of the regions. According to some embodiments of the present invention, each of the first, second, and third regions 1203a-c may have a thickness in the range of about 3 micrometers to about 6 micrometers, and the thermoelectric element 1201 may have a thickness in the range of about 9 micrometers to about 18 micrometers. According to some more embodiments of the present invention, each of the regions 1203a-c may have a thickness of about 5 micrometers, and the thermoelectric element 1201 may have a thickness of about 15 micrometers. According to still other embodiments of the present invention, the thermoelectric element 1201 may have a total thickness in the range of about 3 micrometers to about 15 micrometers.

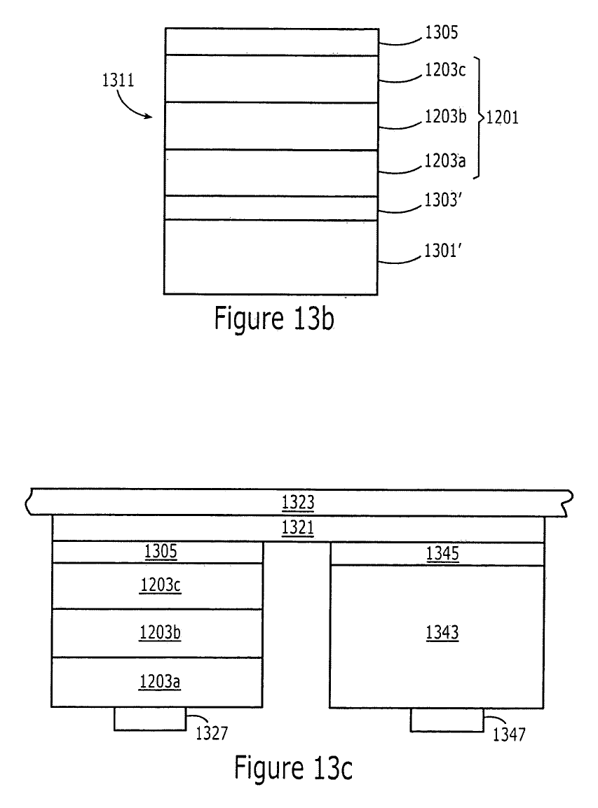

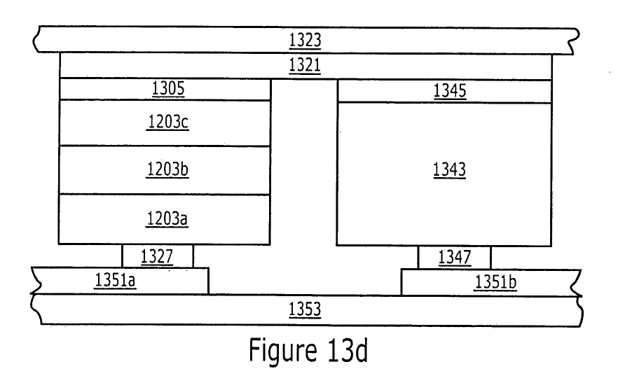

Operations of forming thermoelectric elements and/or devices discussed above with reference to FIG. 12, will now be discussed with reference to FIGS. 13a-d. As shown in FIG. 13a, a single crystal substrate 1301 (such as a GaAs substrate) may be used as a base for epitaxial deposition of the thermoelectric materials used to form the thermoelectric superlattice. First, a buffer layer 1303 may be formed on the substrate 1301 using epitaxial deposition so that the buffer layer 1303 has a single crystal structure aligned with a single crystal structure of the substrate 1301. The buffer layer 1303, for example, may be a layer of Bi₂Te₃ having a thickness in the range of about 0.1 micrometers to about 1.0 micrometers. Buffer layers are discussed, for example, in U.S. Patent Publication No. 2003/0099279 entitled “Phonon-Blocking, Electron-Transmitting Low-Dimensional Structures”, the disclosure of which is hereby incorporated herein in its entirety by reference.

After forming the buffer layer 1303, the thermoelectric superlattice layers 1203a′, 1203b′, and 1203c′ may be formed using epitaxial deposition to provide the superlattice structures discussed above with respect to FIG. 12. Epitaxial deposition of thermoelectric superlattices is discussed, for example, in U.S. Pat. Nos. 6,300,150 and 6,071,351 and in U.S. Patent Publication No. 2003/0099279, the disclosures of which are hereby incorporated herein in their entirety by reference. Superlattice structures are further discussed in the references by Venkatasubramanian et al. entitled “Phonon-Blocking Electron-Transmitting Structures” (18^{th} International Conference on Thermoelectrics, 1999, pages 100-103) and “Thin-Film Thermoelectric Devices With High Room-Temperature Figures Of Merit” (Nature, Vol. 413, 11 Oct. 2001, pages 597-602), the disclosures of which are hereby incorporated herein in their entirety by reference. Separate substrates may be used to form thermoelectric superlattice layers for n-type and p-type thermoelectric elements. Stated in other words, one substrate (or a plurality of substrates) may be diced to form p-type thermoelectric elements, and another substrate (or another plurality of substrates) may be used to form n-type thermoelectric elements.

After forming the superlattice layers discussed above, the substrate 1301 and the layers thereon may be diced to provide a separate thermoelectric element 1311 with a portion 1301′ and 1303′ of the substrate and buffer layer remaining thereon as shown in FIG. 13b. Moreover, an interconnect metallization 1305 may be provided on a surface of the resulting thermoelectric elements either before or after dicing the substrate. The interconnect metallization 1305, for example, may include an adhesion metal layer (such as a layer of chromium, titanium, and/or tungsten) and a barrier metal layer (such as a layer of gold and/or nickel), with the adhesion metal layer between the barrier metal layer and the thermoelectric superlattice structure. Moreover, the resulting superlattice regions 1203a-c may be the same as discussed above with respect to FIG. 12.

As shown in FIG. 13c, the thermoelectric element including the superlattice regions 1203a-c may be bonded to a conductive trace 1321 on a thermally conductive carrier 1323 (such as an AIN substrate), and the portions 1301′ and 1303′ of the substrate and buffer layer may be removed. Moreover, the portions 1301′ and 1303′ of the substrate and buffer layer may be removed before or after bonding the thermoelectric element to the carrier 1323. More particularly, solder may be used to bond the interconnection metallization 1305 to the conductive trace 1321, and a second interconnection metallization 1327 may be provided on the thermoelectric element opposite the first interconnection metallization 1305. Like the first interconnection metallization, the second interconnection metallization may include an adhesion metal layer (such as a layer of chromium, titanium, and/or tungsten) between a barrier metal layer (such as a layer of gold and/or nickel) and the thermoelectric element.

In addition, a second thermoelectric element 1343 may be bonded to the conductive trace 1321 using interconnection metallization 1345. Moreover, the first thermoelectric element (including superlattice regions 1203a-c) and the second thermoelectric element 1343 may have different conductivity types to provide a p-n thermoelectric couple for a thermoelectric device providing thermoelectric heating and/or cooling. The second thermoelectric element 1343 may have a homogeneous superlattice period as discussed, for example, in the reference by Venkatasubramanian et al. entitled “Phonon-Blocking Electron-Transmitting Structures”, or a heterogeneous superlattice period as discussed above with respect to FIG. 12. In still other alternatives, the second thermoelectric-element 1343 may be a bulk thermoelectric element of a single thermoelectric material without a superlattice structure.

As shown in FIG. 13d, the interconnection metallizations 1327 and 1347 may be bonded to respective conductive traces 1351a-b on the thermally conductive substrate 1353, for example, using solder. The thermoelectric elements are thus thermally coupled in parallel between the two thermally conductive substrates 1323 and 1353 and electrically coupled in series through the conductive traces 1321 and 1353a-b to provide thermoelectric cooling and/or power generation.

According to additional embodiments of the present invention, relatively thick thermoelectric elements may be provided by bonding two thermoelectric elements of the same conductivity type, and the two bonded thermoelectric elements may be thermally coupled in series between two thermally conductive plates of a thermoelectric device. Accordingly, two relatively thin thermoelectric elements with relatively high quality crystal structure may be bonded to provide a relatively thick thermoelectric element without requiring a single thick epitaxial deposition that may otherwise result in a reduced quality of crystal structure. Stated in other words, a quality of two bonded thermoelectric elements may be higher than that of a single thick thermoelectric element because of possible difficulties in the epitaxial deposition of a single thick thermoelectric layer.

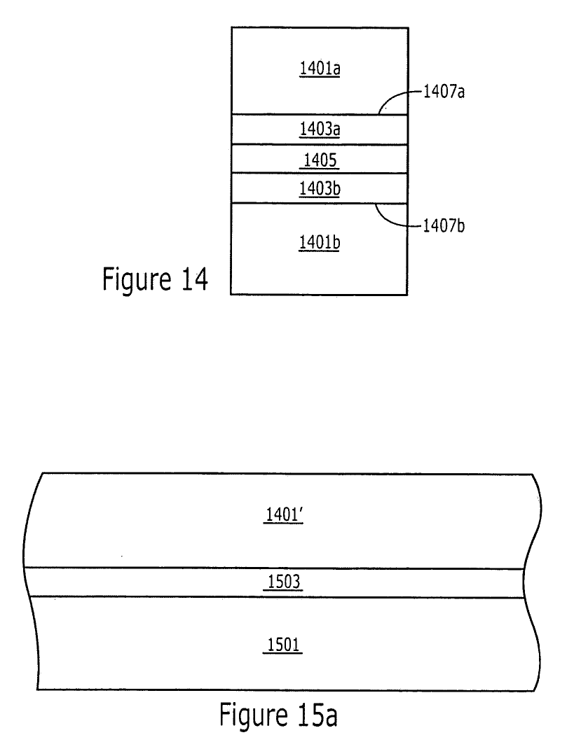

As shown in FIG. 14, the first and second thermoelectric elements 1401a-b of the same conductivity type may be bonded using first and second interconnection metallizations 1403a-b and solder 1405. More particularly, each of the interconnection metallizations 1403a-b may include an adhesion metal layer (such as a layer of chromium, titanium, and/or tungsten) between a barrier metal layer (such as a layer of gold and/or nickel) and the respective thermoelectric element. Moreover, each of the thermoelectric elements 1401a-b may include a superlattice of alternating thermoelectric layers, and a period of the superlattices of the thermoelectric elements 1401a and/or 1401b may be homogeneous as discussed in the reference by Venkatasubramanian et al. entitled “Phonon-Blocking Electron-Transmitting Structures”, or heterogeneous as discussed above with respect to FIG. 12.

More particularly, respective surfaces 1407a-b of the first and second thermoelectric elements 1401a-b may be bonded so that a path of current through the first and second thermoelectric elements passes through the alternating layers of the first and second thermoelectric elements. Stated in other words, the first and second thermoelectric elements 1401a-b may be bonded so that the alternating layers of the superlattices of the first and second thermoelectric elements are substantially parallel.

A solder bond may thus be used to bond the first and second thermoelectric elements 14011a-b, and the solder bond may be provided using solder 1405. More particularly, the solder 1405 may include tin (Sn). The solder 1405, for example, may be a lead-tin solder or a lead free solder. According to some embodiments of the present invention, the thermoelectric elements 1401a-b may have a p-type conductivity including a superlattice of alternating layers of Bi₂Te₃ and Sb₂Te₃. According to some other embodiments of the present invention, the thermoelectric elements 1401a-b may include a superlattice may have an n-type conductivity including alternating layers of Bi₂Te₃ and Bi₂Te₃₋ₓSeₓ, and/or alternating layers of PbTe and PbTeSe, and/or alternating layers of Bi₂Te₃ and InₓTe_{y}. By way of example, the thermoelectric elements 1401a-b may have an n-type conductivity including a superlattice of alternating layers of Bi₂Te₃ and Bi₂Te₃₋ₓSeₓ, (with x in the range of about 0.2 to about 0.4). According to some embodiments of the present invention, the first and second thermoelectric elements 1401a-b may have a same thickness, and a combined thickness through the first and second thermoelectric elements 1401a-b (including interconnection metallizations 1403a-b and solder 1405) after bonding may be in the range of about 10 micrometers to about 20 micrometers.

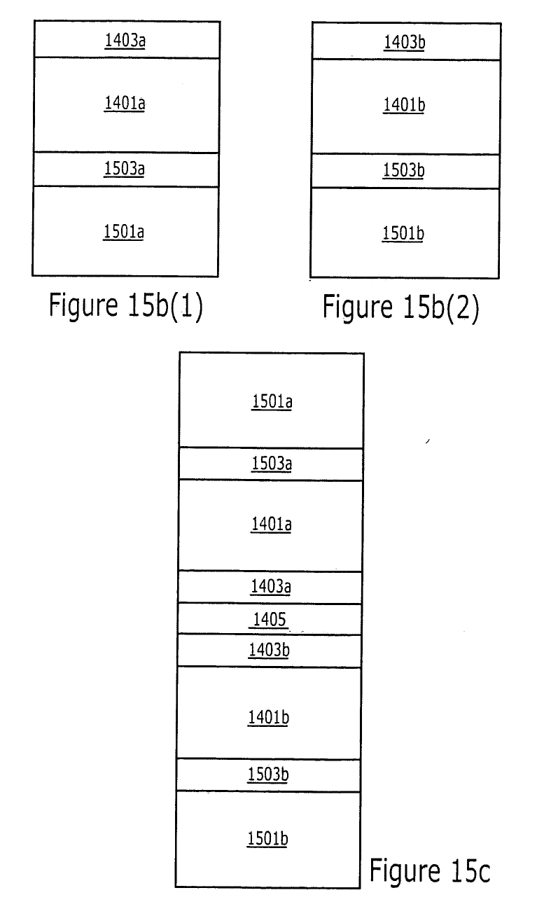

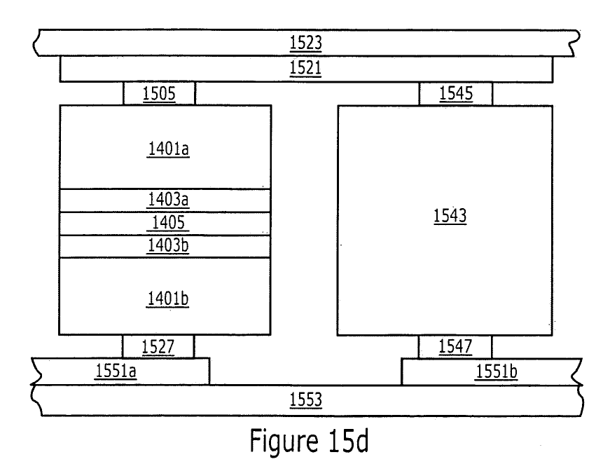

Operations of forming thermoelectric elements and/or devices discussed above with reference to FIG. 14, will now be discussed with reference to FIGS. 15a-d. As shown in FIG. 15a, a single crystal substrate 1501 (such as a GaAs substrate) may be used as a base for epitaxial deposition of the thermoelectric materials used to form the thermoelectric superlattices. First, a buffer layer 1503 may be formed on the substrate 1501 using epitaxial deposition so that the buffer layer 1503 has a single crystal structure aligned with a single crystal structure of the substrate 1501. The buffer layer 1503, for example, may be a layer of Bi₂Te₃ having a thickness in the range of about 0.1 micrometers to about 1.0 micrometers.

After forming the buffer layer 1503, the thermoelectric superlattice layer 1401′ may be formed using epitaxial deposition to provide a superlattice structure as discussed above with respect to FIG. 12. The superlattice structure of the layer 1401 may have a homogeneous period as discussed in the reference by Venkatasubramanian et al. entitled “Phonon-Blocking Electron-Transmitting Structures”, or a heterogeneous period as discussed above with reference to FIGS. 12 and 13a. Separate substrates may be used to form thermoelectric superlattice layers for n-type and p-type thermoelectric elements. Stated in other words, one substrate (or a plurality of substrates) may be diced to form p-type thermoelectric elements, and another substrate (or another plurality of substrates) may be used to form n-type thermoelectric elements. Moreover, separate substrates may be used to form the first and second thermoelectric elements 1401a-b of FIG. 14 (of the same conductivity type) so that the first and second thermoelectric elements may have the same or different superlattice structures, periods, materials, etc.

After forming the superlattice layers discussed above, the substrate(s) 1501 and the layers thereon may be diced to provide separate thermoelectric elements 1401a and 1401b with portions 1501a-b and 1503a-b of the substrate and buffer layer remaining thereon. Moreover, interconnect metallizations 1403a-b may be provided on surfaces of the resulting thermoelectric elements either before or after dicing the substrate(s). The interconnect metallizations 1403a-b, for example, may include an adhesion metal layer (such as a layer of chromium, titanium, and/or tungsten) and a barrier metal layer (such as a layer of gold and/or nickel), with the adhesion metal layer between the barrier metal layer and the respective thermoelectric superlattice structure. Moreover, the resulting thermoelectric elements 1401a-b may be the same as discussed above with respect to FIG. 14.

As shown in FIG. 15c, the first and second thermoelectric elements 1401a-b (together with the portions 1501a-b and 1503a-b of the substrate and buffer layer) may be bonded using solder bond 1405. In an alternative, the portions 1501a-b of the substrate and/or the portions 1503a-b of the buffer layer may be removed before bonding. The portions 1501a-b of the substrate and the portions 1503a-b of the buffer layer may be removed to provide the structure of FIG. 14. Accordingly, the thermoelectric elements 1401a-b and the metal interconnection layers 1403a-b and 1505 may together provide a combined thermoelectric element 1559 as shown in FIG. 15d.

As shown in FIG. 15d, the combined thermoelectric element 1559 may be bonded to a conductive trace 1521 on a thermally conductive carrier 1523 (such as an AlN substrate). More particularly, interconnection metallization 1505 (for example, including adhesion, barrier, and solder metal layers) may be used to bond the combined thermoelectric element 1559 to the conductive trace 1521. The interconnection metallization 1505 may include an adhesion metal layer (such as a layer of chromium, titanium, and/or tungsten) between a barrier metal layer (such as a layer of gold and/or nickel) and the combined thermoelectric element, and a solder layer between the barrier metal layer and the conductive trace 1521.

In addition, a second thermoelectric element 1543 may be bonded to the conductive trace 1321 using interconnection metallization 1545. Moreover, the first thermoelectric element 1559 (including first and second thermoelectric elements 1401a-b of the same conductivity type) and the second thermoelectric element 1543 may have different conductivity types to provide a p-n thermoelectric couple for a thermoelectric device providing thermoelectric heating and/or cooling. The second thermoelectric element 1543 may have a homogeneous superlattice period as discussed, for example, in the reference by Venkatasubramanian et al. entitled “Phonon-Blocking Electron-Transmitting Structures”; a heterogeneous superlattice period as discussed above with respect to FIG. 12; or multiple thermoelectric elements separated by metal interconnection layers as discussed above with respect to FIG. 14. In still other alternatives, the second thermoelectric element 1543 may be a bulk thermoelectric element of a single thermoelectric material without a superlattice structure.

In addition, the thermoelectric elements 1559 and 1543 may be bonded to respective conductive traces 1551a-b on the thermally conductive substrate 1553 using interconnection metallizations 1527 and 1547. The interconnection metallization 1527 may include an adhesion metal layer (such as a layer of chromium, titanium, and/or tungsten) between a barrier metal layer (such as a layer of gold and/or nickel) and the combined thermoelectric element 1559, and a solder layer between the barrier metal layer and the conductive trace 1551a. Similarly, the interconnection metallization 1547 may include an adhesion metal layer (such as a layer of chromium, titanium, and/or tungsten) between a barrier metal layer (such as a layer of gold and/or nickel) and the thermoelectric element 1543, and a solder layer between the barrier metal layer and the conductive trace 1551b. The thermoelectric elements 1559 and 1543 are thus thermally coupled in parallel between the two thermally conductive substrates 1523 and 1553 and electrically coupled in series through the conductive traces 1521 and 1553a-b to provide thermoelectric cooling and/or power generation. Moreover, the thermoelectric elements 1401a-b are electrically and thermally coupled in series between the thermally conductive substrates 1523 and 1553 to provide a combined thermoelectric element 1559 having an increased thickness;

According to some additional embodiments of the present invention, relatively thick and/or high resistivity thermoelectric elements having superlattice structures may provide improved performance. A thermoelectric element, for example, may include a plurality of alternating layers of different thermoelectric materials, and a thickness of the superlattice may be at least about 3 micrometers, and more particularly, at least about 7 micrometers. According to some embodiments of the present invention, the superlattice may be a p-type conductivity superlattice including alternating layers of Bi₂Te₃ and Sb₂Te₃. Moreover, the p-type conductivity superlattice may have a thickness of at least about 10 micrometers, and a resistivity of at least about 0.6×10⁻³ ohm-cm, and more particularly, a thickness of about 0.8×10⁻³ ohm-cm. According to other embodiments of the present invention, the superlattice may be an n-type conductivity superlattice including alternating layers of Bi₂Te₃ and Bi₂Te₃₋ₓSeₓ, and/or alternating layers of n—PbTe and n—PbTeSe, and/or alternating layers of n—Bi₂Te₃ and n—InₓTe_{y}. By way of example, the superlattice may be an n-type conductivity superlattice including alternating layers of Bi₂Te₃ and Bi₂Te₃₋ₓSeₓ (with x in the range of about 0.2 to about 0.4). Moreover, the 1-type conductivity superlattice may have a thickness of at least about 10 micrometers, and a resistivity of at least about 2×10⁻³ ohm-cm, and more particularly, a thickness of about 2.5×10⁻³ ohm-cm.

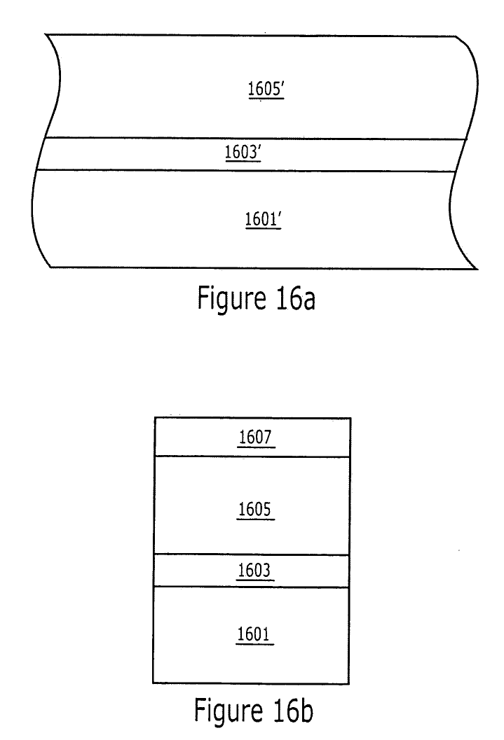

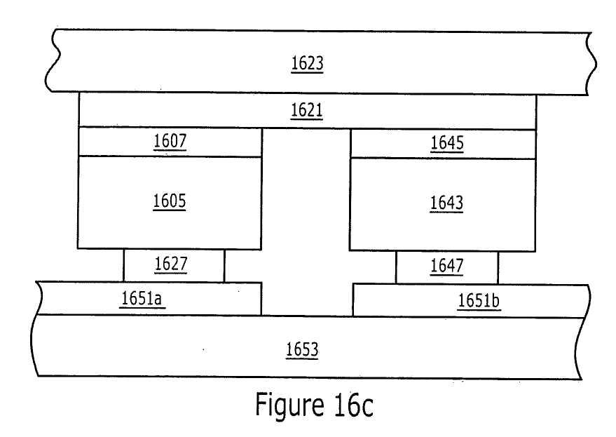

As shown in FIG. 16a, a single crystal substrate 1601′ (such as a GaAs substrate) may be used as base for epitaxial deposition of the alternating layers of different thermoelectric materials making up the relatively thick superlattice. Before forming the superlattice, a buffer layer 1603′ may be formed on the substrate 1601′ using epitaxial deposition so that the buffer layer 1603′ has a single crystal structure aligned with a single crystal structure of the substrate 1601′. The buffer layer 1603′, for example, may be a layer of Bi₂Te₃ having a thickness in the range of about 0.1 micrometers (μm) to about 1.0 micrometers (μm).

After forming the buffer layer 1603′, the thermoelectric superlattice 1605′ may be formed using epitaxial deposition to provide the superlattice structures discussed above. Epitaxial deposition of thermoelectric superlattices is discussed, for example, in U.S. Pat. Nos. 6,300,150 and 6,071,351 and in U.S. Patent Publication No. 2003/0099279, the disclosures of which are hereby incorporated herein in their entirety by reference. Superlattice structures are further discussed in the references by Venkatasubramanian et al. entitled “Phonon-Blocking Electron-Transmitting Structures” (18^{th} International Conference on Thermoelectrics, 1999, pages 100-103) and “Thin-Film Thermoelectric Devices With High Room-Temperature Figures Of Merit” (Nature, Vol. 413, 11 Oct. 2001, pages 597-602), the disclosures of which are hereby incorporated herein in their entirety by reference. Separate substrates may be used to form thermoelectric superlattice layers for n-type and p-type thermoelectric elements. Stated in other words, one substrate (or a plurality of substrates) may be diced to form p-type thermoelectric elements, and another substrate (or another plurality of substrates) may be used to form n-type thermoelectric elements.

According to some embodiments of the present invention, the superlattice 1605′ may be a p-type conductivity superlattice including alternating layers of Bi₂Te₃ and Sb₂Te₃. Moreover, the p-type conductivity superlattice may have a thickness of at least about 10 micrometers, and a resistivity of at least about 0.6×10⁻³ ohm-cm, and more particularly, a thickness of about 0.8×10⁻³ ohm-cm. According to other embodiments of the present invention, the superlattice 1605′ may be an n-type conductivity superlattice including alternating layers of Bi₂Te₃ and Bi₂Te₃₋ₓSeₓ, and/or alternating layers of n—PbTe and n—PbTeSe, and/or alternating layers of n—Bi₂Te₃ and n—InₓTe_{y}. By way of example, the superlattice 1605′ may be an n-type conductivity superlattice including alternating layers of Bi₂Te₃ and Bi₂Te₃₋ₓSeₓ (with x in the range of about 0.2 to about 0.4). Moreover, the n-type conductivity superlattice may have a thickness of at least about 10 micrometers, and a resistivity of at least about 2×10⁻³ ohm-cm, and more particularly, a thickness of about 2.5×10⁻³ ohm-cm.

After forming the superlattice 1605′ as discussed above, the substrate 1601′ and the layers thereon may be diced to provide a separate thermoelectric element 1605 with a portion 1601 and 160′ of the substrate and buffer layer remaining thereon as shown in FIG. 16b. Moreover, an interconnect metallization 1607 may be provided on a surface of the resulting thermoelectric elements either before or after dicing the substrate. The interconnect metallization 1607, for example, may include an adhesion metal layer (such as a layer of chromium, titanium, and/or tungsten) and a barrier metal layer (such as a layer of gold and/or nickel), with the adhesion metal layer between the barrier metal layer and the thermoelectric superlattice 1605. Moreover, the resulting superlattice 1605 may be the same as discussed above with respect to FIG. 12 and/or FIGS. 15b(1-2).

As shown in FIG. 16c, the thermoelectric element-including the superlattice 1605 may be bonded to a conductive trace 1621 on a thermally conductive carrier 1623 (such as an AlN substrate), and the portions 1601 and 1603 of the substrate and buffer layer may be removed. Moreover, the portions 1601 and 1603 of the substrate and buffer layer may be removed before or after bonding the thermoelectric element to the carrier 1623. More particularly, solder may be used to bond the interconnection metallization 1607 to the conductive trace 1621, and a second interconnection metallization 1627 may be provided on the thermoelectric element opposite the first interconnection metallization 1607. Like the first interconnection metallization, the second interconnection metallization may include an adhesion metal layer (such as a layer of chromium, titanium, and/or tungsten) between a barrier metal layer (such as a layer of gold and/or nickel) and the thermoelectric element.

In addition, a second thermoelectric element 1643 may be bonded to the conductive trace 1621 using interconnection metallization 1645. Moreover, the first thermoelectric element including superlattice 1605 and the second thermoelectric element 1643 may have different conductivity types to provide a p-n thermoelectric couple for a thermoelectric device providing thermoelectric heating and/or cooling. The second thermoelectric element 1643 may have a homogeneous superlattice period as discussed, for example, in the reference by Venkatasubramanian et al. entitled “Phonon-Blocking Electron-Transmitting Structures”, or a heterogeneous superlattice period as discussed above with respect to FIG. 12. In still other alternatives, the second thermoelectric element 1643 may be a bulk thermoelectric element of a single thermoelectric material without a superlattice structure.

In addition, the interconnection metallizations 1627 and 1647 may be bonded to respective conductive traces 1651a-b on the thermally conductive substrate 1653, for example, using solder. The thermoelectric elements are thus thermally coupled in parallel between the two thermally conductive substrates 1623 and 1653 and electrically coupled in series through the conductive traces 1621 and 1653a-b to provide thermoelectric cooling and/or power generation.

While the present invention has been particularly shown and described with reference to embodiments thereof, it will be understood by those of ordinary skill in the art that various changes in form and details may be made therein without departing from the spirit and scope of the present invention as defined by the following claims.

1. A method of forming a thermoelectric device comprising:
forming a thermoelectric superlattice including a plurality of alternating layers of different thermoelectric materials wherein a period of the alternating layers varies over a thickness of the superlattice.

2. A method according to claim 1 wherein forming the superlattice comprises depositing the superlattice on a single crystal substrate using epitaxial deposition.

3. A method according to claim 2 further comprising:
removing the single crystal substrate from the superlattice;
providing a second thermoelectric superlattice wherein the first and second thermoelectric superlattices have opposite conductivity types; and
thermally coupling the first and second thermoelectric superlattices in parallel between two thermally conductive plates while electrically coupling the first and second thermoelectric superlattices in series.

4. A method according to claim 1 wherein the alternating layers of different thermoelectric materials comprises alternating layers of Bi₂Te₃ and Sb₂Te₃.

5. A method according to claim 4 wherein the superlattice comprises a p-type conductivity superlattice.

6. A method according to claim 1 wherein the alternating layers of different thermoelectric materials comprises alternating layers of Bi₂Te₃ and Bi₂Te₃₋ₓSeₓ or alternating layers of n—PbTe and n—PbTeSe, or alternating layers of n—Bi₂Te₃ and n—InₓTe_{y}.

7. A method according to claim 6 wherein the superlattice comprises an n-type conductivity superlattice.

8. A method according to claim 1 wherein the alternating layers comprise alternating layers of two different materials wherein a period of the alternating layers is defined as a combined thickness of two adjacent layers of the different materials.

9. A method according to claim 8 wherein a first period of a first region of the superlattice is at least 10 percent greater than a second period of a second region of the superlattice.

10. A method according to claim 8 wherein a first period of a first region of the superlattice is at least 20 percent greater than a second period of a second region of the superlattice.

11. A method according to claim 8 wherein a first period of a first region of the superlattice is at least 40 percent greater than a second period of a second region of the superlattice.

12. A method according to claim 8 wherein a first region of the superlattice has a first thickness in the range of about 1 micrometer to about 7 micrometers, wherein a second region of the superlattice has a second thickness in the range of about 1 micrometers to about 7 micrometers, wherein the first region has a first period in the range of about 20 Angstroms to about 100 Angstroms, wherein the second region has a second period in the range of about 20 Angstroms to about 100 Angstroms, and wherein the second period is at least 10 percent greater than the first period.

13. A method according to claim 12 wherein a third region of the superlattice has a third thickness in the range of about 1 micrometer to about 7 micrometers, wherein the third region has a third period in the range of about 20 Angstroms to about 100 Angstroms, and wherein the third period is at least 10 percent greater than the second period.

14. A method according to claim 12 wherein the superlattice has a total thickness in the range of about 3 micrometers to about 15 micrometers.

15. A thermoelectric device comprising:
a thermoelectric superlattice including a plurality of alternating layers of different thermoelectric materials wherein a period of the alternating layers varies over a thickness of the superlattice.

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. A method of forming a thermoelectric device comprising:
providing first and second thermoelectric elements of a same conductivity type, with each of the first and second thermoelectric elements including a respective superlattice of alternating layers of different thermoelectric materials; and
bonding respective surfaces of the first and second thermoelectric elements so that a path of current through the first and second thermoelectric elements passes through the alternating layers of the first and second thermoelectric elements.

29. A method according to claim 28 wherein bonding the respective surfaces comprises solder bonding the respective surfaces of the first and second thermoelectric elements.

30. A method according to claim 29 wherein solder bonding comprises solder bonding using a solder including tin (Sn).

31. A method according to claim 29 wherein bonding the respective surfaces comprises:
forming first and second barrier metal layers on the respective surfaces of the first and second thermoelectric elements; and
forming a solder bond between the first and second barrier metal layers wherein the solder bond and the first and second barrier metal layers comprise different metals.

32. A method according to claim 31 wherein bonding the respective surfaces further comprises:
before forming the first and second barrier metal layers, forming first and second adhesion metal layers on the respective surfaces of the first and second thermoelectric elements wherein the first and second adhesion metal layers and the first and second barrier metal layers comprise different metals.

33. A method according to claim 28 further comprising:
thermally coupling the first and second thermoelectric elements in series between two thermally conductive plates, wherein the first and second thermoelectric elements have a first conductivity type;
thermally coupling a third thermoelectric element between the two thermally conductive plates, wherein the third thermoelectric element has a second conductivity type different than the first conductivity type, and wherein the first, second, and third thermoelectric elements are electrically coupled in series.

34. A method according to claim 33 further comprising:
thermally coupling a fourth thermoelectric element having the second conductivity type in series with the third thermoelectric element between the first and second thermally conductive plates, wherein the first, second, third, and fourth thermoelectric elements are electrically coupled in series.

35. A method according to claim 28 wherein the first and second thermoelectric elements each comprise alternating layers of Bi₂Te₃ and Sb₂Te₃.

36. A method according to claim 35 wherein the first and second thermoelectric elements comprise p-type conductivity thermoelectric elements.

37. A method according to claim 28 wherein the first and second thermoelectric elements each comprises alternating layers of Bi₂Te₃ and Bi₂Te₃₋ₓSeₓ or alternating layers of n—PbTe and n—PbTeSe, or alternating layers of n—Bi₂Te₃ and n—InₓTe_{y}.

38. A method according to claim 37 wherein the first and second thermoelectric elements comprise n-type conductivity thermoelectric elements.

39. A method according to claim 28 wherein each of the first and second thermoelectric elements has a same thickness and wherein a combined thickness through the first and second thermoelectric elements after bonding the first and second thermoelectric elements is in the range of about 10 to about 20 micrometers.

40. A thermoelectric device comprising:
first and second thermoelectric elements of a same conductivity type, wherein each of the first and second thermoelectric elements includes a respective superlattice of alternating layers of different thermoelectric materials, and wherein respective surfaces of the first and second thermoelectric elements are bonded with metal therebetween so that a path of current through the first and second thermoelectric elements passes through the alternating layers of the first and second thermoelectric elements.

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. A method of forming a thermoelectric device, the method comprising:
forming a single crystal thermoelectric superlattice comprising a plurality of alternating layers of different thermoelectric materials wherein a thickness of the single crystal thermoelectric superlattice is at least about 3 micrometers.

53. A method according to claim 52 wherein the single crystal thermoelectric superlattice comprises a p-type conductivity superlattice.

54. A method according to claim 53 wherein the alternating layers of different thermoelectric materials comprises alternating layers of Bi₂Te₃ and Sb₂Te₃.

55. A method according to claim 53 wherein the thickness of the single crystal thermoelectric superlattice is at least about 10 micrometers.

56. A method according to claim 53 wherein a resistivity of the single crystal thermoelectric superlattice is at least about 0.6×10⁻³ ohm-cm.

57. A method according to claim 56 wherein the resistivity of the single crystal thermoelectric superlattice is about 0.8×10⁻³ ohm-cm.

58. A method according to claim 52 wherein the single crystal thermoelectric superlattice comprises an n-type conductivity superlattice.

59. A method according to claim 58 wherein the alternating layers of different thermoelectric materials comprises alternating layers of Bi₂Te₃ and Bi₂Te₃₋ₓSeₓ, or alternating layers of n—PbTe and n—PbTeSe, or alternating layers of n—Bi₂Te₃ and n—InₓTe_{y}.

60. A method according to claim 59 wherein the thickness of the single crystal thermoelectric superlattice is at least about 8 micrometers.

61. A method according to claim 58 wherein a resistivity of the single crystal thermoelectric superlattice is at least about 2×10⁻³ ohm-cm.

62. A method according to claim 61 wherein the resistivity of the single crystal thermoelectric superlattice is about 2.5×10⁻³ ohm-cm.

63. A method according to claim 52 further comprising:
forming a second single crystal thermoelectric superlattice wherein the first and second single crystal thermoelectric superlattices have different conductivity types; and
thermally coupling the first and second single crystal thermoelectric superlattices are in parallel between first and second thermally conductive plates wherein the first and second single crystal thermoelectric superlattices are electrically coupled in series.

64. A method according to claim 52 wherein forming the single crystal thermoelectric superlattice comprises:
forming the single crystal thermoelectric superlattice on a single crystal substrate; and
removing the single crystal substrate.

65. A thermoelectric device comprising:
a single crystal thermoelectric superlattice comprising a plurality of alternating layers of different thermoelectric materials wherein a thickness of the single crystal thermoelectric superlattice is at least about 3 micrometers.

66. (canceled)

67. (canceled)

68. (canceled)

69. (canceled)

70. (canceled)

71. (canceled)

72. (canceled)

73. (canceled)

74. (canceled)

75. (canceled)

76. (canceled)
